(19) United States
(12) Patent Application Publication
(10) Pub. No.: US 2008/0077834 A1
(43) Pub. Date: Mar. 27, 2008

(54) Deterministic Diagnostic Information Capture from Memory Devices with Built-in Self Test

(76) Inventors: Ajay Khoche, San Jose, CA (US); Klaus-Dieter Hilliges, Shanghai (CN)

Correspondence Address: VERIGY, 4700 INNOVATION WAY, BLDG D1, FORT COLLINS, CO, 80528, US

(21) Appl. No.: 11/535,979

(22) Filed: Sep. 27, 2006

(51) Int. Cl. G01R 31/28

(52) U.S. Cl. 714/732

(57) ABSTRACT

From a memory device comprising a memory circuit and a built-in self-test system (BIST), diagnostic information is deterministically obtained by using the BIST to perform a test sequence that tests the memory circuit. The test sequence comprises writing one or more test patterns at memory locations in the memory circuit and reading respective output patterns from the memory locations. Diagnostic patterns corresponding to the output patterns are losslessly compressed to generate compressed diagnostic information. The compressed diagnostic information is temporarily stored and, at one or more predetermined points in the test sequence, the compressed diagnostic information is output from the memory device under test. Losslessly compressing the diagnostic patterns and outputting the resulting compressed diagnostic information at predetermined points in the test sequence provides the diagnostic information deterministically, which allows the diagnostic information to be received by conventional, deterministically-operating ATE.

### RELATED APPLICATIONS

This disclosure is related to the following United States patent applications filed on the filing date of this disclosure: Ser. No. ______, of Khoche et al. entitled Diagnostic Information Capture from Memory Devices with Built-in Self Test (Docket no. 10060523) and Ser. No. ______ of Khoche et al. entitled Automatic Test Equipment Receiving Diagnostic Information from Devices with Built-in Self Test (Docket no. 10060524). The above disclosures are assigned to the assignee of this disclosure and are incorporated herein by reference.

### BACKGROUND

The ever-increasing complexity of integrated circuits, especially memory devices, i.e., integrated circuits that comprise memory circuits, has led to memory devices being designed with a built-in self-test system (BIST) to facilitate testing during manufacture. Automatic test equipment (ATE) is still used to test the memory device, but the automatic test equipment simply controls the BIST and evaluates a test result generated by the BIST.

A memory device that incorporates a built-in self test system typically comprises a memory circuit and a BIST. The BIST comprises a pattern generator, an address generator and a control generator that respectively provide test patterns and expected patterns, addresses and control signals via respective multiplexers to the data inputs, address inputs and control inputs of the memory circuit. The test patterns are written at memory locations in the memory circuit and respective output patterns are then read from the memory locations. The output pattern read from each memory location is compared with a corresponding expected pattern identical to the test pattern that was written at the memory location to determine whether a difference exists. Differences, if any, detected between the output patterns and the corresponding expected patterns are accumulated in the BIST to generate a cumulative difference. At the end of the test sequence, the cumulative difference is output to the host ATE as the test result for the memory device under test. The ATE evaluates the cumulative difference to determine whether it indicates that the testing has detected a difference between any of the output patterns and its corresponding expected pattern. A difference indicates that the memory device under test is faulty.

Outputting a cumulative difference significantly reduces the volume of communication traffic between the BIST and the host ATE. However, the cumulative difference only allows the ATE to determine whether the memory device under test as a whole has passed or failed the test sequence. The lossy data compression involved in generating the cumulative difference prevents the ATE from identifying the portion of the memory circuit that has caused the device under test to fail the test. Such information is highly desirable, especially to allow process optimization during production ramp-up but also during on-going production to facilitate process control.

FIG. 1A is a block diagram of an example of a memory device under test 10 being tested by automatic test equipment 12. Memory device 10 comprises a memory circuit 14 and a built-in self-test system (BIST) 16. Sellers of commercially-available BISTs include Synopsys, Inc., Mountain View, Calif. and Mentor Graphics Corp., Wilsonville, Oreg.

The example of BIST 16 shown is composed of a pattern generator (PG) 20, an address generator (AG) 24, a control signal generator (CG) 28 and multiplexers 34, 36 and 38. Multiplexers 34, 36 and 38 each have two inputs and an output, and are interposed between the outputs of pattern generator 20, address generator 24 and control signal generator 28, respectively, and the data input (DATA), address input (ADR) and control input (CTRL) of memory circuit 14. Pattern generator 20, address generator 24 and control signal generator 28 are connected to one input of multiplexers 34, 36 and 38, respectively. The functional data input FD, the functional address input FA and the functional control input FC of memory device 10 are connected to the other input of multiplexers 34, 36 and 38, respectively. Functional data input FD, functional address input FA and functional control input FC are the inputs of memory device 10 used for data, address and control signals, respectively, during in-service operation of memory device 10, i.e., during operation of memory device 10 except when it is being tested by BIST 16. During in-service operation of memory device 10, multiplexers 34, 36 and 38 connect the functional data input FD, the functional address input FA and the functional control input FC, respectively, of memory device 10 to the data input (DATA), address input (ADR) and control input (CTRL), respectively, of memory circuit 14.

BIST 16 additionally comprises a difference detector and accumulator (DDA) 22. Difference detector and accumulator 22 has an output pattern input OP, an expected pattern input EP and a cumulative difference output CD. Output pattern input OP is connected to the read output (RO) of memory circuit 14 to receive the output patterns read from the memory locations of memory circuit 14 defined by the addresses generated by address generator 24 and in response to the control signals generated by control signal generator 28. Expected pattern input EP is connected to the output of pattern generator 20 to receive a corresponding expected pattern corresponding to each output pattern received at output pattern input OP. The corresponding expected pattern is identical to the test pattern written at the memory location of memory circuit 14 from which the output pattern was read. Difference detector and accumulator 22 detects any difference between each output pattern and its corresponding expected pattern and accumulates such difference to generate the above-described cumulative difference. Cumulative difference output CD is connected to ATE 12. At the end of the test sequence performed by BIST 16, difference detector and accumulator 22 outputs the cumulative difference to ATE 12 via cumulative difference output CD.

BIST 16 additionally comprises a BIST controller 26 that communicates with ATE 12 directly or via other logic, such as a JTAG port (not shown). BIST controller 26 controls the operation of difference detector and accumulator 22, pattern generator 20, address generator 24 and control signal generator 28. During operation of BIST 16 to test memory device under test 10, control signals output by BIST controller 26 cause multiplexers 34, 36 and 38 to connect the outputs of pattern generator 20, address generator 24, control signal generator 28, respectively, to the data input (DATA), address input (ADR) and control input (CTRL), respectively, of memory circuit 14. The control signals output by BIST controller 26 additionally cause pattern generator 20, address generator 24 and control signal generator 28 to generate the test patterns and expected patterns, the addresses and the WRITE and READ commands, respectively, used to test memory circuit 14. At the end of the test sequence, a control signal output by BIST controller 26 to a control input C of difference detector and accumulator 22 causes difference detector and accumulator 22 to output the cumulative difference to ATE 12 via its cumulative difference output CD.

FIG. 1B is a flow chart illustrating the operation of BIST 16 described above with reference to FIG. 1A to test memory circuit 14 that forms part of memory device 10 under test. Execution begins at block 50. In block 52, BIST controller 26 is initialized. Once initialized, BIST controller 26 generates control signals that cause pattern generator 20, address generator 24 and control signal generator 28 to generate the test patterns and expected patterns, the addresses and the WRITE and READ commands, respectively, used to test memory circuit 14. Typically, the control signals generated by BIST controller 26 cause pattern generator 20, address generator 24 and control signal generator 28 to execute one or more memory test algorithms, e.g., a march algorithm. Examples of march algorithms include MARCH C-, MARCH LR, etc. Other suitable algorithms include Walking One, Walking Zero, Checkerboard, Address Unique, GALPAT, etc. Address generator 24 generates addresses that walk across entire memory circuit 14 and pattern generator 20 generates one or more test patterns that are written at memory locations in memory circuit 14 and additionally generates the corresponding expected patterns that difference detector and accumulator 22 compares with the output patterns read from memory circuit 14. Any difference between the output pattern and the corresponding expected pattern indicates a faulty memory location in memory circuit 14. Control signal generator 28 generates control signals that determine the READ or WRITE mode of memory circuit 14.

In block 54, the test pattern generated by pattern generator 20 is written at a memory location in memory circuit 14 defined by an address generated by address generator 24. In block 56, a respective output pattern is read from the memory location in memory circuit 14 defined by the address generated by address generator 24, i.e., the memory location at which the test pattern was written in block 54.

Typically, in block 54, a single test pattern is written at multiple memory locations in memory circuit 14 and, in block 56, such multiple memory locations are sequentially read to provide respective output patterns. Alternatively, multiple test patterns are written at multiple memory locations in block 54 before the memory locations are sequentially read to provide respective output patterns in block 56.

In block 58, difference detector and accumulator 22 compares the output pattern read from the memory location in block 56 with the corresponding expected pattern generated by pattern generator 20 to detect whether the output pattern differs from the expected pattern. Difference detector and accumulator 22 accumulates the differences detected to generate a cumulative difference.

In block 60, a test is performed to determine whether all the tests in the test sequence have been performed. A NO result returns execution to block 54 so that another test can be performed. A YES result advances execution to block 62.

In block 62, difference detector and accumulator 22 outputs the cumulative difference to ATE 12 as the test result for memory device under test 10. Any difference indicated by the cumulative difference indicates that memory device under test 10 is faulty. However, the cumulative difference does not identify the faulty memory location(s) in memory device under test 10.

FIG. 1C is a block diagram of an example of difference detector and accumulator 22 of memory device under test 10. In the example shown, the output pattern read from a memory location in memory circuit 14 and the corresponding expected pattern generated by pattern generator 20 are each N-bit quantities. Difference detector and accumulator 22 is composed of N channels labelled CH₁ to CH_{N}. Each channel receives a respective bit of the output pattern OP and a corresponding bit of the corresponding expected pattern EP, and generates a respective bit of the cumulative difference D.

Each channel of difference detector and accumulator 22 is composed of an exclusive-OR (XOR) gate 71, an OR gate 73 and a flip-flop 75. In channel CH₁, for example, the inputs of XOR gate 71 are connected to receive the first bit OP₁ of the output pattern and the first bit EP₁ of the corresponding expected pattern. The output of XOR gate 71 is connected to one input of OR gate 73. The output of OR gate 73 is connected to the D-input of flip-flop 75. The Q-output of flip-flop 75 is connected to the other input of OR gate 73 and additionally provides the first bit D₁ of the cumulative difference CD output by difference detector and accumulator 22. Flip-flop 75 additionally has a clock input and a reset line respectively connected to a clock line and a reset line. Neither the clock line nor the reset line is shown to simplify the drawing. The remaining channels CH₂-CH_{N} of difference detector and accumulator 22 are identical in structure to channel CH₁. Each channel CH₂-CH_{N} receives a respective bit OP₂-OP_{N} of the output pattern and the corresponding bit EP₂-EP_{N} of the corresponding expected pattern and generates a respective bit D₂-D_{N} of the cumulative difference.

At the start of testing memory device 10, a reset signal on the reset line resets the Q-outputs of flip-flops 75 to a logical 0. After the first test performed on memory device 10, in each channel of difference detector and accumulator 22, the bit of the output pattern and the bit of the corresponding expected pattern are identical provided that the tested memory location is not faulty, as is typical. Consequently, the output of XOR gate 71 remains a logical 0. The logical 0s on both inputs of OR gate 73 cause the output of OR gate 73 to be a logical 0. The next clock pulse applied to the clock input of flip-flop 75 clocks the logical 0 on the D-input to the Q-output. Thus, after each non-faulty memory location of memory device 14 is tested, the respective bit of the cumulative difference output by the channel remains a logical 0.

In an example of memory device 10 in which one or more of the memory locations is faulty, in at least one channel of difference detector and accumulator 22, the bit of the output pattern output by such memory location differs from the corresponding bit of the corresponding expected pattern. The difference causes the output of the corresponding XOR gate 71 to change to a logical 1. The logical 1 applied to one input of OR gate 73 causes the output of OR gate 73 to change to a logical 1. The next clock pulse applied to the clock input of flip-flop 75 clocks the logical 1 on the D-input to the Q-output. Thus, the first time in the test sequence that a bit of the output pattern differs from the corresponding bit of the corresponding expected pattern, the respective bit of the cumulative difference output by the channel changes to a logical 1.

Then, in all tests subsequently performed on the faulty memory device, the logical 1 applied to the input of OR gate 73 by the Q-output of flip-flop 75 holds the output of OR gate 73 and, hence, the D-input of flip-flop 75, at a logical 1 regardless of the result of the test and the consequent state of the output of XOR gate 71. Thus, the bit of the cumulative difference set to a logical 1 by the bit of the output pattern received from the faulty memory location remains as a logical 1 to the end of the test sequence. Other bits of the cumulative difference can be changed to a logical 1 by subsequently-tested faulty memory locations and will remain as a logical 1 until the end of the test sequence.

At the end of the test sequence performed by BIST 16, ATE 12 evaluates the cumulative difference output by memory device 10 as the test result for memory device under test 10. Any one bit of the cumulative difference that is a logical 1 indicates to the ATE that the memory device under test is faulty, and the ATE categorizes memory device under test 10 as bad. However, the cumulative difference does not identify the one or more faulty memory locations.

Conventional automatic test equipment operates deterministically. The test routine performed by ATE 12 causes the ATE to receive the test result from device under test 10 concurrently with BIST 16 reaching the end of the test sequence and outputting the test result. This significantly reduces the volume of communication traffic between the BIST and the host ATE, but only allows the ATE to determine whether the memory device under test as a whole has failed at least one test in the test sequence. Outputting only a test result prevents the ATE from identifying the memory locations in memory circuit 14 that have caused memory device under test 10 to be categorized as bad. Such diagnostic information is highly desirable, especially to allow process optimization during production ramp-up but also during on-going production to facilitate process control.

Accordingly, what is needed is a way to obtain diagnostic information from a memory device under test having a built-in self-test system. What also is needed is a way to obtain such diagnostic information when conventional, deterministically-operating automatic test equipment is used to test the memory device.

### BRIEF DESCRIPTION OF THE DRAWINGS

FIG. 1A is a block diagram showing an example of a conventional memory device under test having a built-in self test system (BIST) being tested by conventional automatic test equipment.

FIG. 1B is a flow chart illustrating the operation of the BIST shown in FIG. 1A to test the memory circuit that forms part of the memory device under test.

FIG. 1C is a block diagram showing an example of the difference detector and accumulator of the memory device under test shown in FIG. 1A.

FIG. 2 is a flow chart showing an example of a method in accordance with an embodiment of the invention for deterministically obtaining diagnostic information from a memory device having a memory circuit and a BIST.

FIG. 3 is a block diagram showing an example of a system in accordance with an embodiment of the invention for deterministically obtaining diagnostic information from a memory device having a BIST, and an example of a memory device having a BIST in accordance with an embodiment of the invention in which the memory device deterministically provides diagnostic information.

FIG. 4 is a block diagram showing an example of a difference pattern generator that may be used as the difference pattern generator in the memory device shown in FIG. 3.

FIG. 5 is a flow chart illustrating the operation of the system shown in FIG. 3 to test the memory circuit of the memory device under test.

FIG. 6 is a block diagram showing an example of a system in accordance with an embodiment of the invention for deterministically obtaining diagnostic information from a memory device having a BIST, and an example of a memory device having a BIST in accordance with an embodiment of the invention in which the memory device deterministically provides diagnostic information.

FIG. 7 is a block diagram showing an example of a difference generator and accumulator that may be used as the difference generator and accumulator of the memory device shown in FIG. 6.

FIG. 8 is a flow chart illustrating the operation of the system shown in FIG. 6 to test the memory circuit of the memory device under test.

### DETAILED DESCRIPTION

As noted above, the BIST of a memory device tests the memory circuit of the memory device by performing a test sequence in which one or more test patterns are written at memory locations in the memory circuit, output patterns are read from the memory locations at which the test patterns were written and difference patterns are generated. Each difference pattern represents the difference between the output pattern read from a memory location in the memory circuit and a corresponding expected pattern identical to the test pattern that was written at the memory location. While diagnostic information can be obtained by outputting every output pattern read by the BIST or by outputting every difference pattern generated by the BIST from the memory device under test to the ATE, such an approach would be difficult to implement in practice due to the very large communications bandwidth required. An alternative is to provide diagnostic information by outputting a few diagnostic patterns from the memory device under test to the ATE as whenever a fault is detected, as described by the inventors in U.S. patent application Ser. No. ______, (docket no. 10060523), mentioned above. However, since a fault can be detected at any arbitrary point in the test sequence, this approach requires that the ATE operate non-deterministically to receive the diagnostic information. As noted above, conventional automatic test equipment operates deterministically.

The invention is based on the observation that the set of difference patterns obtained from the output patterns read when the BIST tests a typical memory device under test is characterized by a run of identical difference patterns interrupted, in a faulty memory device only, by one or more non-identical difference patterns.

Known lossless data compression schemes are capable of providing very large compression ratios when applied to a set of difference patterns characterized as just described. Applying such a lossless data compression scheme to such a set of difference patterns generates compressed diagnostic information many times smaller in size than the original set of difference patterns. The actual size of the compressed diagnostic information depends on the number of faulty memory locations. Provided that the maximum number of faulty memory locations that can reasonably be expected is relatively small, as is typical, a memory device under test can incorporate a lossless compressor to generate compressed diagnostic information by subjecting the difference patterns to lossless compression and all the compressed diagnostic information generated by the entire test sequence performed by the BIST to test the memory device under test can be stored in a buffer small enough to be incorporated into the memory device. The buffer can be sufficiently small that it does not significantly increase the die area, and, hence, the cost of the memory device.

Temporarily storing the compressed diagnostic information allows the memory device under test to output the compressed diagnostic information at one or more predetermined points in the test sequence, for example, at the end of the test sequence. Outputting the compressed diagnostic information at one or more predetermined points in the test sequence allows the ATE that tests the memory device under test to operate deterministically. Compressing the difference patterns losslessly allows the original difference patterns to be recovered from the compressed diagnostic information output from the memory device under test.

As noted above, the set of difference patterns generated from the output patterns read by the BIST is characterized by a long run of identical difference patterns each of which indicates no difference between an output pattern and its corresponding expected pattern. Such a difference pattern will be called a no-difference pattern. In a fault-free memory device under test, the run of no-difference patterns is uninterrupted. In a memory device with one or more faulty memory locations, the run of no-difference patterns is interrupted by one or more difference-indicating patterns. A difference-indicating pattern is a difference pattern that indicates a difference between an output pattern and its corresponding expected pattern. The difference-indicating patterns are different from the no-difference pattern, and may differ from one another. A difference-indicating pattern is generated from the output pattern read from each faulty memory location. Such an output pattern differs from its corresponding expected pattern and will be called a fault-indicating output pattern. The number of fault-indicating output patterns read during the test sequence is at least equal to the number of faulty memory locations in the memory circuit, and is typically more than the number of faulty memory locations because the test sequence performed by the BIST typically tests each memory location more than once, e.g., by writing different test patterns at each memory location. The position of each difference-indicating pattern in the set of difference patterns identifies the faulty memory location. The difference-indicating pattern itself indicates the failure mode of the faulty memory location.

The limitation on the number of faulty memory locations whose compressed diagnostic information can be temporarily stored in a buffer of a given size can be increased or even eliminated by dividing the test sequence into blocks, losslessly compressing the difference patterns corresponding to the output patterns read during execution of each block of the test sequence, and outputting the compressed diagnostic information to the ATE at predetermined points in the test sequence, namely, at the end of each block of the test sequence. Again, outputting the compressed diagnostic information at predetermined points in the test sequence allows the ATE to operate deterministically. In this approach, each block of the test sequence can be regarded as a test sequence that is smaller in size than the test sequence that completely tests the memory device under test. The ATE temporarily stores the compressed diagnostic information received from the memory device under test at the end of each block of the test sequence to accumulate the compressed diagnostic information for the full test sequence.

The blocks into which the test sequence is divided can range in size from blocks as large as one-half of the test sequence to substantially smaller blocks. A smaller block size reduces the compression efficiency of the lossless compression process but decreases the size of the buffer needed to accommodate the compressed diagnostic information generated by a memory device having a given maximum number of faulty memory locations. Moreover, outputting a given quantity of compressed diagnostic information using multiple, small output operations takes more time than using fewer, larger output operations.

The blocks into which the test sequence is divided are typically equal in size but are not necessarily so as long as the size of each block is defined. Equal-sized blocks cause the memory device under test to output the compressed diagnostic information at regular intervals, and allows the ATE to be programmed to receive the compressed diagnostic information at the same regular intervals. Irregularly-sized blocks merely complicate the programming of the ATE since the ATE has to receive the compressed diagnostic information output at known, but irregular, intervals.

One exemplary lossless compression scheme that provides a very high compression ratio when applied to a set of difference patterns characterized as described above is run-length coding. Examples of other lossless compression schemes that can be used are Huffman coding and Dictionary coding, both known in the data compression art. Run-length coding is used in various picture and video compression schemes such as JPEG and MPEG.

In run-length coding a set of difference patterns, each uninterrupted run of identical difference patterns is represented by a respective value pair. The value pair is composed of a pair of values, namely, the difference pattern itself and the number of the difference patterns in the uninterrupted run.

Conventional run-length coding represents the single run of no-difference patterns generated by a fault-free memory device under test by a single value pair composed of the no-difference pattern and the number of no-difference patterns in the run. The number of no-difference patterns is equal to the number of output patterns read from the memory circuit during the test sequence. Conventional run-length coding uses two value pairs to represent the difference patterns generated by a memory device under test in which only one of the output patterns read during the test sequence is a fault-indicating output pattern. In an example in which the fault-indicating output pattern is the n-th output pattern read during the test sequence, the first value pair is composed of the no-difference pattern and the number (n−1) of no-difference patterns in the run of no-difference patterns generated before the fault-indicating output pattern was read. The second value pair is composed of the difference-indicating pattern that indicates the difference between the fault-indicating output pattern and its corresponding expected pattern, and one, i.e., the number of difference-indicating patterns in the run of difference-indicating patterns.

The compressed diagnostic information for a memory device under test in which only one of the output patterns read during the test sequence is a fault-indicating output pattern may additionally include a third value pair. The third value pair is composed of the no-difference pattern and the number of no-difference patterns in the run of no-difference patterns generated from the output patterns read from the memory circuit after the read operation that produced the fault-indicating output pattern. However, such additional value pair is typically unnecessary as the number of read operations performed by the BIST in executing the test sequence is known.

More generally, using conventional run-length coding, the number of value pairs needed to represent up to m non-consecutive difference-indicating patterns is equal to twice the number of non-consecutive difference-indicating patterns, i.e., 2m. In embodiments in which the test sequence is divided into blocks, references above to the test sequence apply to each block of the test sequence.

The buffer used to store the compressed diagnostic information is sized widthwise to accommodate the above-mentioned value pairs and depthwise to accommodate the number of value pairs corresponding to a maximum number of non-consecutive difference-indicating patterns likely to be generated during the test sequence. In embodiments in which the test sequence is divided into blocks, the buffer is sized depthwise to accommodate the number of value pairs corresponding to a maximum number of non-consecutive difference-indicating patterns likely to be generated in a block of the test sequence.

The size of the compressed diagnostic information can be further reduced by using a modified run-length coding scheme in which a single value represents the number of consecutive no-difference patterns. A single value can be used for this purpose because the no-difference pattern is known. Moreover, if runs of fault-indicating output patterns are unlikely, or if representing each no-difference pattern individually is acceptable, the modified run-length coding scheme can represent each difference-indicating pattern by a single value, namely, the difference-indicating pattern itself. A single value can be used for this purpose because the number (one) of difference-indicating patterns in the run of difference-indicating patterns is known. The modified run-length coding scheme allows all the value pairs used in conventional run-length coding to be replaced by respective single values, which reduces the size of the compressed diagnostic information.

In a typical production start-up environment, the test sequence is initially divided into a number of relatively small blocks. Then, as the production process matures and the production yield increases, the BIST and the ATE are re-programmed to increase the size, and reduce the number, of the blocks. Finally, when the production process is fully mature, the BIST and the ATE are re-programmed to eliminate the blocks altogether so that the buffer stores the compressed diagnostic information for the entire test sequence. If the maximum number of faults in a typical memory device under test later increases to a level that renders the depth of the buffer inadequate to accommodate all the compressed diagnostic information generated during the test sequence, the BIST and the ATE can be re-programmed once more to divide the test sequence into blocks, or to divide the test sequence into smaller blocks.

Expanding the losslessly-compressed diagnostic information output from the memory device under test fully recovers the original difference patterns represented by the compressed diagnostic information. The recovered difference patterns can then be analyzed to identify the test(s) that generated the fault-indicating output patterns, the corresponding memory location(s) and the nature of the fault at each memory location. The expansion and analysis is performed by the ATE used to test the memory device under test. Alternatively, the ATE expands the compressed diagnostic information to recover the original difference patterns and transmits the recovered difference patterns to external apparatus for analysis. In another alternative, the ATE transmits the compressed diagnostic information to external apparatus for expansion and analysis.

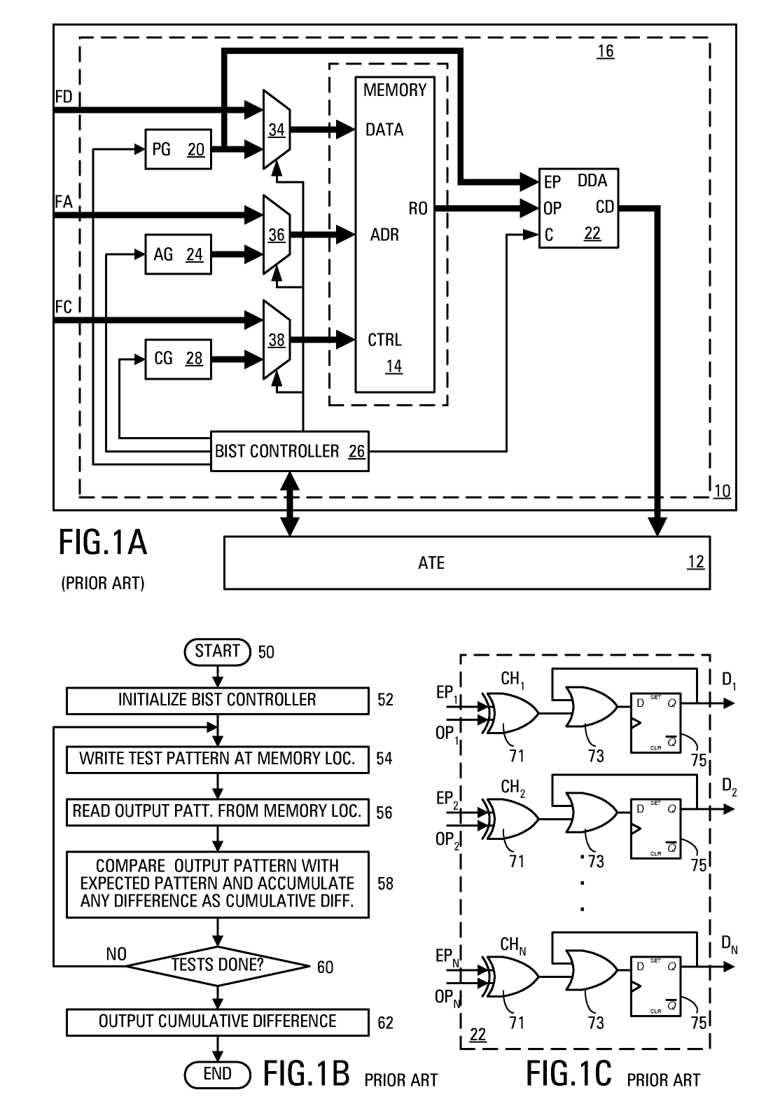

Expansion of the compressed diagnostic information can be performed conditionally: there is little need to expand the compressed diagnostic information received from a memory device under test that is fault-free. In one embodiment, the memory device under test additionally generates and outputs to the ATE a test result as in the conventional memory device described above with reference to FIG. 1A. In another embodiment, the ATE determines the test result for the memory device under test from the compressed diagnostic information received from the memory device under test. In both embodiments, the compressed diagnostic information is expanded only when the test result indicates that the memory device under test is faulty. Moreover, in an embodiment in which the memory device under test additionally generates a conventional test result and outputs the test result to the ATE at the end of the test sequence, output of the compressed diagnostic information can be made conditional on the conventional test result indicating that the memory device under test is faulty.

In embodiments of the memory device in which the BIST writes long runs of identical test patterns at the memory locations in the memory circuit, lossless compression may be applied in a manner similar to that described above to the output patterns read from the memory circuit instead of applying the lossless compression to difference patterns generated from the output patterns. Applying lossless compression to the output patterns provides some simplification because no difference patterns are generated. However, difference patterns still need to be generated in embodiments that maintain compatibility with existing ATE test routines by generating a cumulative difference for output to the ATE as the test result for the memory device under test. Moreover, applying lossless compression to output patterns may be less efficient than applying lossless compression to difference patterns. In typical test sequences, the test pattern written to the memory circuit changes several times causing corresponding changes in the output patterns. Consequently, for many test sequences, the runs of identical output patterns are shorter than the runs of identical difference patterns. Output patterns and difference patterns will be referred to generically as diagnostic patterns.

The buffer is described above as being incorporated within the memory device and the compressed diagnostic information temporarily stored in the buffer is described as being output to the ATE used to test the memory device. Alternatively, the buffer can be incorporated within the ATE. When the buffer is incorporated within the ATE, the compressed diagnostic information is output from the memory device under test to the ATE for temporary storage in the buffer. The compressed diagnostic information output from the memory device to the ATE is sufficiently small in size that outputting the compressed diagnostic information does not require a large communication bandwidth between the memory device under test and the ATE. In a further alternative, part of the buffer is incorporated within the memory device and the remainder of the buffer is incorporated within the ATE.

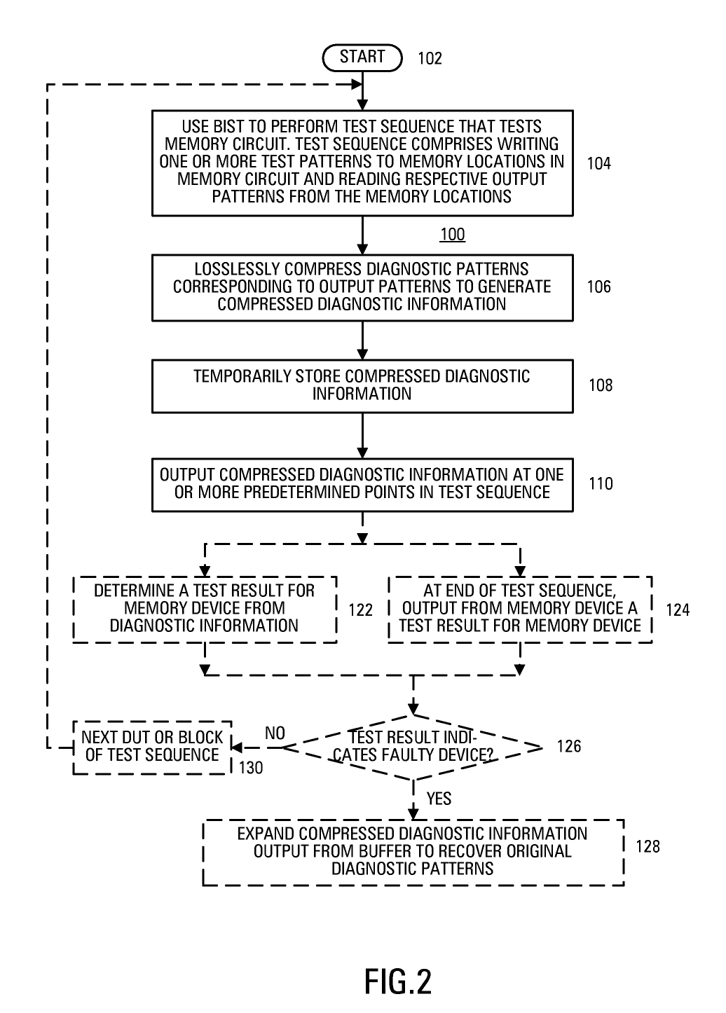

FIG. 2 is a flow chart showing an example of a method 100 in accordance with an embodiment of the invention for deterministically obtaining diagnostic information from a memory device having a memory circuit and a built-in self-test system (BIST). The method outputs compressed diagnostic information at one or more predetermined points in the test sequence. This allows the compressed diagnostic information to be received from the memory device under test using conventional automatic test equipment that operates deterministically. Thus, conventional automatic test equipment with appropriate programming can be used to test a memory device under test that provides such compressed diagnostic information and additionally allows such conventional ATE to receive the compressed diagnostic information from such memory device under test. Structural changes to the conventional ATE are typically unnecessary.

Execution starts at block 102. In block 104, the BIST is used to perform a test sequence that tests the memory circuit of the memory device under test. The test sequence comprises writing one or more test patterns at memory locations in the memory circuit and reading respective output patterns from the memory locations.

In block 106, diagnostic patterns corresponding to the output patterns are losslessly compressed to generate compressed diagnostic information. In an example, run-length coding is used to compress the diagnostic patterns losslessly. In one embodiment, the diagnostic patterns corresponding to the output patterns are the respective output patterns themselves. In another embodiment, a respective difference pattern representing a difference between the output pattern read from a memory location and the corresponding expected pattern, identical to the test pattern that was written at the memory location from which the output pattern was read, is generated. In such embodiment, the diagnostic patterns corresponding to the output patterns are the respective difference patterns. Thus, output patterns or difference patterns between output patterns and corresponding expected patterns will be regarded as diagnostic patterns corresponding to the output patterns. The corresponding expected pattern is a pattern identical to the test pattern written at the memory location from which the output pattern was read. In an example, the corresponding expected pattern is a subsequently-generated pattern identical to the test pattern that was written.

In block 108, the compressed diagnostic information is temporarily stored.

In block 110, the compressed diagnostic information is output at one or more predetermined points in the test sequence. Outputting the compressed diagnostic information at one or more predetermined points in the test sequence allows the compressed diagnostic information that is output to be received deterministically. The receiving apparatus sets itself to receive the compressed diagnostic information after it has performed a number of test cycles whose execution time equals the time required by the BIST to execute the test sequence as far as each predetermined point. Thus, the receiving apparatus is set to receive the compressed diagnostic information at the time the compressed diagnostic information is output by the device under test. The receiving apparatus is typically deterministically-operating ATE, but other types of deterministically-operating test equipment may be used to receive the compressed diagnostic information, and the term automatic test equipment will be taken to encompass such other types of equipment.

In an embodiment, the one or more predetermined points in the test sequence at which the compressed diagnostic information is output is a single predetermined point at the end of the test sequence. This allows the compressed diagnostic information for the entire test sequence to be output in a single output operation, and minimizes the time needed to test the memory device under test. However, as described above, the size of the buffer can be reduced by dividing the test sequence into blocks. In this case, the one or more predetermined points in the test sequence at which the compressed diagnostic information is output is the end of each block of the test sequence. In an example, the compressed diagnostic information for a first block of the test sequence is output at a first predetermined point half way through the test sequence and additional compressed diagnostic information for a second block of the test sequence is output at a second predetermined point at the end of the test sequence. As noted above, simple programming changes may be made to the BIST and to the ATE to reduce the number of predetermined points at which the compressed diagnostic information is output as the production process for the memory device matures and the defect rate falls.

FIG. 2 additionally shows some optional operations that may additionally constitute part of method 100. In block 122, a test result for the device under test is obtained from the diagnostic information. In the example shown, the test result is obtained from the compressed diagnostic information.

In block 126, a test is performed to determine whether the test result indicates that the memory device under test is faulty. A YES result causes execution to advance to block 128, where the compressed diagnostic information is expanded to recover the original diagnostic patterns that were subject to lossless compression in block 106. A NO result causes execution to return to block 104 via block 130, where the next memory device under test is tested or the next block of the test sequence is performed.

In an alternative performed in embodiments in which the lossless compression scheme employed in block 106 generates compressed diagnostic information from which a test result cannot readily be determined, block 128 is performed before block 122 is performed, and, in block 122, the test result for the memory device is determined from the original diagnostic patterns recovered in block 128.

FIG. 2 additionally shows block 124 that can be performed as an alternative to performing block 122. In block 124, the memory device under test outputs the test result. In an embodiment of method 100, the test sequence performed by the BIST in block 104 additionally generates a cumulative difference that, at the end of the test sequence, constitutes the test result for the memory device under test. Then, in block 124, the test result for the memory device under test is output. Outputting a test result at the end of the test sequence provides compatibility with existing ATE test routines that expect to receive a test result at the end of the test sequence. Since the test result is output at the end of the test sequence, the test result can be received by conventional, deterministically-operating ATE. Optionally, in an embodiment having block 124, an embodiment of block 110 in which the compressed diagnostic information is output at a single predetermined point at the end of the test sequence may be moved to between block 126 (YES branch) and block 128.

In an embodiment of method 100, the buffer that temporarily stores the compressed diagnostic information constitutes part of the memory device, and the memory device under test is connected to ATE. In block 108, the memory device under test temporarily stores the compressed diagnostic information in its buffer. In block 110, the memory device under test outputs the compressed diagnostic information stored in its buffer to the ATE at the one or more predetermined points in the test sequence. Thus, in this embodiment, blocks 104, 106, 108 and 110 of method 100 are performed by the memory device under test.

In another embodiment of method 100, the memory device under test is connected to ATE, and the buffer that temporarily stores the compressed diagnostic information constitutes part of the ATE. Blocks 104, 106 and 110 are performed by the memory device under test, and, in block 108, the compressed diagnostic information output by the memory device under test in block 110 is stored in buffer of the ATE. In this embodiment, the test sequence is divided into blocks. In block 106 of method 100, the memory device under test applies lossless compression to the diagnostic patterns generated by each block of the test sequence to generate respective compressed diagnostic information, and, in block 110, the memory device under test outputs the compressed diagnostic information for each block of the test sequence to the ATE at one or more predetermined points in the test sequence, i.e., at the end of each block of the test sequence. Thus, the ATE can operate deterministically to receive the compressed diagnostic information for each block of the test sequence. The ATE performs block 108 to store the compressed diagnostic information received at the end of each block of the test sequence to accumulate the compressed diagnostic information for the entire test sequence in its buffer. This approach eliminates the limitation that the size of a buffer in the memory device under test imposes on the amount of compressed diagnostic information that can be stored. However, performing more than one output operation during the test sequence increases the time required to execute the test sequence.

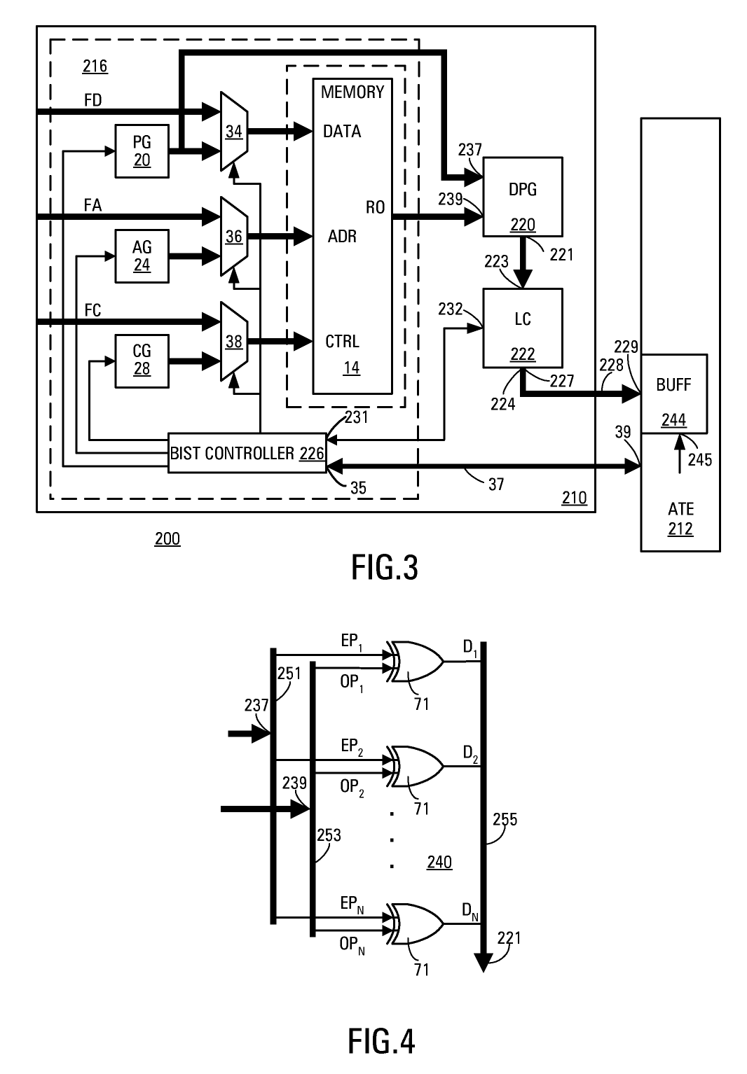

Method 100 is performed at least in part by circuits built into the memory device under test. Examples of such circuits will be described below with reference to FIGS. 3, 4, 6 and 7. In some embodiments, few, if any, additional communication channels are needed between the memory device under test and the automatic test equipment (ATE) used to test the memory device under test.

FIG. 3 is a block diagram showing an example of a system 200 in accordance with an embodiment of the invention for deterministically obtaining diagnostic information from a memory device comprising a memory circuit and a built-in self-test system (BIST). FIG. 3 additionally shows an example of a memory device under test 210 in accordance with an embodiment of the invention. System 200 and memory device 210 each perform a respective embodiment of method 100 described above with reference to FIG. 2 to provide diagnostic information. System 200 comprises memory device 210 and ATE 212. During each block of the test sequence performed by the BIST, memory device 210 generates diagnostic patterns and losslessly compresses the diagnostic patterns to generate compressed diagnostic information. At one or more points in the test sequence, i.e., at the end of each block of the test sequence, memory device 210 outputs the compressed diagnostic information to ATE 212 and ATE 212 operates deterministically to receive the compressed diagnostic information. ATE 212 temporarily stores the compressed diagnostic information received at the end of each block of the test sequence. In this embodiment, ATE 212 incorporates a buffer that temporarily stores the compressed diagnostic information received from memory device under test 210.

Memory device 210 comprises a memory circuit 14, a built-in self-test system (BIST) 216, a difference pattern generator (DPG) 220, a lossless compressor (LC) 222 and a diagnostic information output 227. ATE 212 has a control port 39 and a diagnostic information input 229 and comprises a buffer 244. Buffer 244 has a diagnostic information input 229 and a control input 245. Diagnostic information input 229 provides the diagnostic information input 229 of ATE 212.

The example of BIST 216 shown in FIG. 3 is composed of a pattern generator (PG) 20, an address generator (AG) 24, a control signal generator (CG) 28 and multiplexers 34, 36, and 38. Each multiplexer 34, 36 and 38 has two inputs and an output. Pattern generator 20, address generator 24 and control signal generator 28 are connected to one input of multiplexers 34, 36 and 38, respectively. The functional data input FD, the functional address input FA and the functional control input FC of memory device 210 are connected to the other input of multiplexers 34, 36 and 38, respectively. Functional data input FD, functional address input FA and functional control input FC of memory device 210 are the inputs used for data, address and control signals, respectively, during in-service operation of memory device 210, i.e., during operation of memory device 210 except when it is being tested using BIST 216. The data input (DATA), address input (ADR) and control input (CTRL) of memory circuit 14 are connected to the outputs of multiplexers 34, 36 and 38, respectively.

During in-service operation of memory device 210, multiplexers 34, 36 and 38 connect the functional data input FD, the functional address input FA and the functional control input FC, respectively, of memory device 210 to the data input (DATA), address input (ADR) and control input (CTRL), respectively, of memory circuit 14.

BIST 216 additionally comprises a BIST controller 226. BIST controller 226 has a control port 35 and a control port 231. A control path 37 connects control port 35 to the control port 39 of ATE 212. BIST controller 226 generates control signals that control the operation of pattern generator 20, address generator 24, control signal generator 28, multiplexers 34, 36 and 38, and lossless compressor 220. During testing of memory device 210, the control signals output by BIST controller 226 cause multiplexers 34, 36 and 38 to connect the outputs of pattern generator 20, address generator 24, control signal generator 28, respectively, to the data input (DATA), address input (ADR) and control input (CTRL), respectively, of memory circuit 14. Control signals output by BIST controller 226 additionally cause pattern generator 20, address generator 24, control signal generator 28 to generate the test patterns and expected patterns, the addresses and the WRITE and READ commands, respectively, used to test memory circuit 14. Additionally, BIST controller 226 exchanges control signals with the control port 39 of ATE 212 via control port 35 and control path 37.

Difference pattern generator 220 has an expected pattern input 237, an output pattern input 239 and a difference pattern output 221. Output pattern input 239 is connected to the read output (RO) of memory circuit 14 to receive the output patterns read from the memory locations of memory circuit 14 defined by the addresses generated by address generator 24 and in response to the control signals generated by control signal generator 28. Expected pattern input 237 is connected to the output of pattern generator 20 to receive the corresponding expected patterns corresponding to the output patterns received at output pattern input 239. As indicated above, the corresponding expected patterns are identical to the test patterns written at the memory locations of memory circuit 14 from which the output patterns are read.

Lossless compressor 222 has a diagnostic pattern input 223, a control port 232 and a compressed diagnostic information output 224. In this embodiment, the difference patterns generated by difference pattern generator 220 from the output patterns read from memory circuit 14 provide the diagnostic patterns corresponding to the output patterns. Accordingly, diagnostic pattern input 223 is connected to the difference pattern output 221 of difference pattern generator 220. Control port 232 is connected to the control port 231 of BIST controller 226. Compressed diagnostic information output 224 provides the diagnostic information output 227 of memory device 210. A diagnostic information path 228 connects diagnostic information output 227 to the diagnostic information input 229 of ATE 212. Lossless compressor circuits suitable for use as lossless compressor 222 are known in the art and will therefore not be described here.

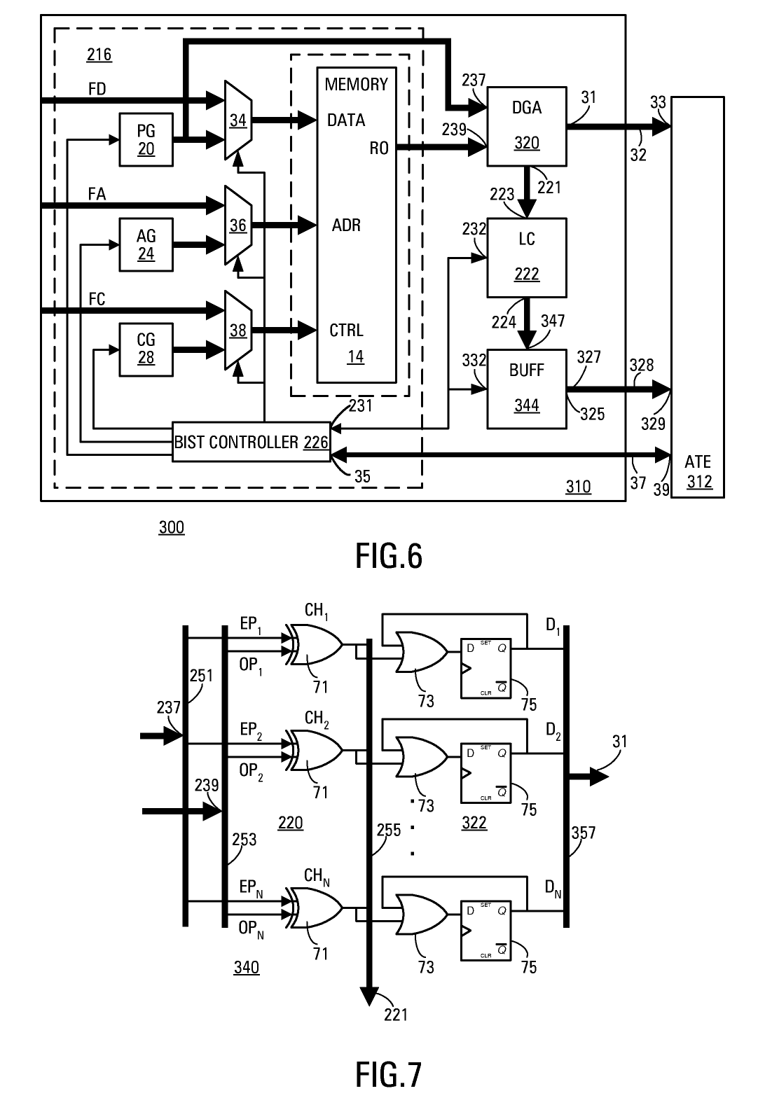

In some embodiments of memory device 210, lossless compressor 222 applies to the difference patterns received from difference pattern generator 220 a lossless compression scheme that generates compressed diagnostic information in a format that does not allow a test result for memory device under test 210 to be easily determined from the compressed diagnostic information. When such a compression scheme is used, the compressed diagnostic information has to be expanded at least partially before the test result can be determined. In such embodiments, a difference generator and accumulator similar to difference generator and accumulator 320 described below with reference to FIG. 6 can be substituted for difference pattern generator 220. Such difference generator and accumulator has a test result output connected by a test result path to a test result input of the ATE, also as described below.

Diagnostic information path 228 is shown in FIG. 3 as a multi-conductor parallel path. A single conductor may be used to provide diagnostic information path 228 by interposing a multiplexer (not shown) between diagnostic information output 227 and diagnostic information path 228 and by interposing a demultiplexer (not shown) between diagnostic information path 228 and the diagnostic information input 229 of ATE 212. Transmitting the compressed diagnostic information as a serial bit stream significantly reduces the number of pins of the package of memory device 210 and the number of communication channels of ATE 212 required to transfer the compressed diagnostic information from memory device under test 210 to ATE 212. In an embodiment of ATE 212 capable of handling the compressed diagnostic information received at diagnostic information input 229 as a serial bit stream, no demultiplexer is needed between diagnostic information path 228 and diagnostic information input 229. In another embodiment, the compressed diagnostic information is serially shifted out of the compressed diagnostic information output 224 of lossless compressor 222.

In an embodiment, either or both of difference pattern generator 220 and lossless compressor 222 comprises additional logic (not shown) controlled by BIST controller 226.

Such additional logic ensures that difference pattern generator 220 can generate a difference pattern and that lossless compressor 222 can subject such difference pattern to lossless compression only when BIST controller 226 is in a compare state.

FIG. 4 is a block diagram showing an example of a difference pattern generator 240 that may be used as difference pattern generator 220 in memory device 210 described above with reference to FIG. 3. Elements of difference pattern generator 240 that correspond to elements of above-described difference pattern generator 220 are indicated by the same reference numerals and will not be described in detail again.

In the example shown, the output pattern read from memory circuit 14 and the corresponding expected pattern generated by pattern generator 20 are each N-bit quantities.

Difference pattern generator 240 is composed of N two-input exclusive-OR (XOR) gates 71.

A respective conductor (not shown) of an expected pattern bus 251 connects one input of each XOR-gate 71 to expected pattern input 237. A respective conductor (not shown) of an output pattern bus 253 connects the other input of each XOR-gate 71 to output pattern input 239. A respective conductor (not shown) of a difference pattern bus 255 connects the output of each XOR gate 71 to difference pattern output 221.

The output of each XOR gates 71 provides a respective bit D₁, D₂, . . . , D_{N} of a difference pattern that represents the modulus of the difference between each bit of the output pattern received at output pattern input 239 and the corresponding bit of the corresponding expected pattern received at expected pattern input 237. Difference pattern bus 255 connects each difference pattern collectively generated by XOR gates 71 to difference pattern output 221.

Each XOR gate 71 receives at its inputs a respective bit (e.g., bit OP₁) of the output pattern and the corresponding bit (e.g., bit EP₁) of the corresponding expected pattern. Typically, each bit of the output pattern is identical to the corresponding bit of the corresponding expected pattern so that the output of each XOR gate 71 is a logical 0. As a result, the difference pattern output at difference pattern output 221 is the no-difference pattern that has a logical 0 in every bit position. A difference between any bit of the output pattern and the corresponding bit of the corresponding expected pattern sets the output of the respective XOR gate 71 to a logical 1. As a result, the difference pattern output at difference pattern output 221 is a difference-indicating pattern that has a logical 1 at each bit position at which the output pattern differs from the corresponding expected pattern and that has a logical 0 at each remaining bit position. The logical ones and logical zeroes may be interchanged.

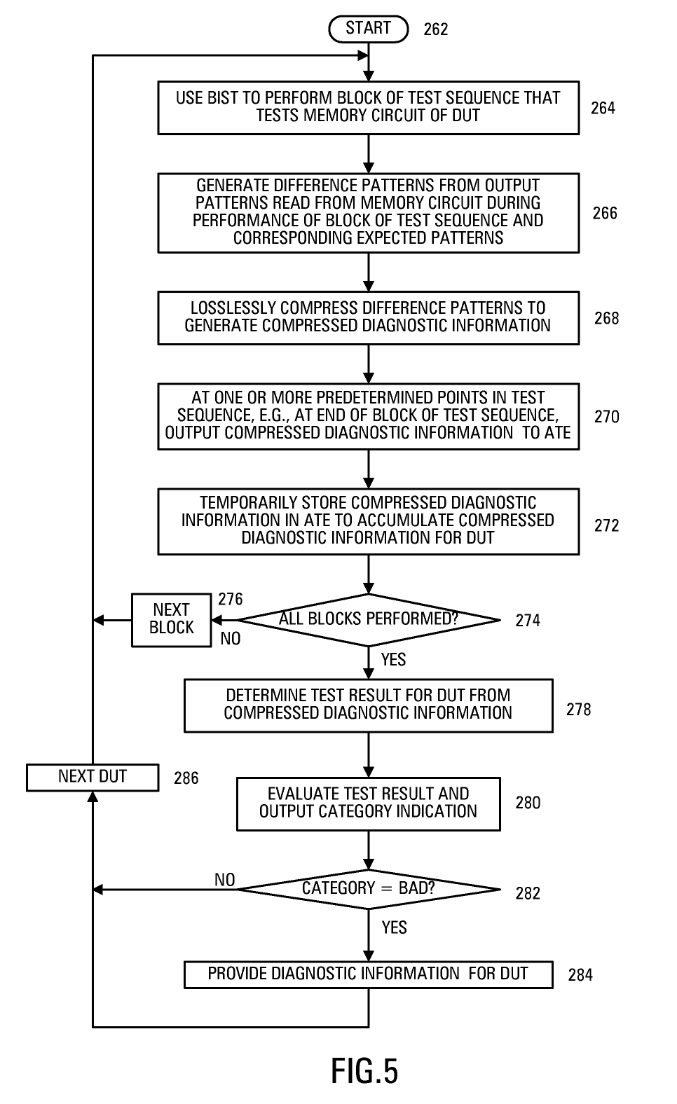

Operation of system 200 to test the memory circuit 14 of memory device under test 210 will now be described with reference to the flow chart shown in FIG. 5 and with additional reference to FIG. 3. In the example shown, the test sequence performed by BIST 216 is divided into blocks.

Execution starts at block 262, where ATE 212 initiates testing memory device under test 210 by providing a start testing command to BIST controller 226 via control path 37.

In block 264, BIST 216 performs one block of a test sequence to test the memory circuit 14 of device under test 210. During operation of BIST 216 to perform the block of the test sequence, control signal generator 28 generates a control signal that sets memory circuit 14 to its write mode, address generator 24 generates an address signal that defines a memory location in memory circuit 14 and pattern generator 20 generates a test pattern that is written at the memory location in memory circuit 14. In response to further control signals provided by BIST controller 226, address generator 24 generates an address signal that again defines the memory location in memory circuit 14 at which the test pattern was written, control signal generator 28 generates a control signal that sets memory circuit 14 to its read mode, and memory circuit 14 reads the respective output pattern from the memory location defined by the address signal.

In some embodiments, BIST 216 generates a single test pattern, writes such test pattern at a single memory location in memory circuit 14 and reads the respective output pattern from the single memory location. During the read operation, BIST 216 additionally generates the test pattern anew as a corresponding expected pattern for input to the expected pattern input 237 of difference pattern generator 220.

In another embodiment, BIST 216 generates a single test pattern, writes such test pattern at multiple memory locations in the memory circuit and sequentially reads the memory locations to provide respective output patterns. The BIST repetitively generates the test pattern anew as a corresponding expected pattern for input to the expected pattern input 237 of difference pattern generator 220.

In yet another embodiment, BIST 216 generates multiple test patterns, writes such test patterns at multiple memory locations in the memory circuit and sequentially reads the memory locations to provide respective output patterns. The BIST additionally generates the multiple test patterns anew as corresponding expected patterns for input to the expected pattern input 237 of difference pattern generator 220.

As an alternative to generating the test pattern(s) anew for input to expected pattern input 237 as the corresponding expected pattern(s), BIST 216 stores the original test pattern(s) and outputs the stored test pattern(s) as the corresponding expected pattern(s). As a further alternative, during the write operation, BIST 216 additionally outputs the original test pattern(s) to the expected pattern input 237 of difference pattern generator 220, where the test pattern(s) are stored as respective corresponding expected pattern(s). Difference pattern generator 220 then generates the difference pattern(s) from the output pattern(s) received at output pattern input 239 and the stored corresponding expected pattern(s).

In block 266, difference patterns are generated from the output patterns read from the memory circuit during performance of the block of the test sequence and their corresponding expected patterns. The output patterns are input to the output pattern input 239 of difference pattern generator 220 and the corresponding expected patterns are input to the expected pattern input 237 of difference pattern generator 220.

Difference pattern generator 220 generates a difference pattern from each output pattern received at output pattern input 239 and its corresponding expected pattern received at expected pattern input 237 and outputs the difference pattern at difference pattern output 221.

In block 268, the difference patterns generated in block 266 are losslessly compressed to generate compressed diagnostic information for the block of the test sequence. Lossless compressor 222 receives the difference patterns generated by difference pattern generator 220 from the output patterns read from memory locations in memory circuit 14 during execution of the block of the test sequence performed by BIST 216. Lossless compressor 222 losslessly compresses the difference patterns to provide the compressed diagnostic information at diagnostic information output 227.

In block 270, at one or more predetermined points in the test sequence memory device under test 210 outputs the compressed diagnostic information to ATE 212. In this example, lossless compressor 222 outputs the compressed diagnostic information at the end of each block of the test sequence performed by BIST 216. The compressed diagnostic information is output at diagnostic information output 227 and passes via diagnostic information path 228 to the diagnostic information input 229 of ATE 212.

In block 272, the compressed diagnostic information for the block of the test sequence is temporarily stored in the ATE to accumulate the compressed diagnostic information for the entire test sequence. ATE 212 receives the compressed diagnostic information at the diagnostic information input 229 of buffer 244. ATE 212 provides a control signal to the control input 245 of buffer 244 concurrently with the end of each block of the test sequence performed by BIST 216, i.e., concurrently with each of the one or more predetermined points in the test sequence. The control signal causes buffer 244 to store temporarily the compressed diagnostic information received at diagnostic information input 229. As BIST 216 performs successive blocks of the test sequence to test memory device under test 210, buffer 244 stores the compressed diagnostic information output at the end of each block of the test sequence and accumulates the compressed diagnostic information for the entire test sequence performed to test memory device under test 210. Optionally, ATE may evaluate the compressed diagnostic information received at the end of each block of the test sequence to determine whether it represents one or more fault-indicating diagnostic patterns and discards the newly-received compressed diagnostic information if it does not. Run-length coded compressed diagnostic information obtained from difference patterns and having only a single value pair or a single value is indicative of no fault-indicating diagnostic patterns.

In block 274, a test is performed to determine whether all the blocks of the test sequence have been performed. A NO result causes execution to return to block 264 via block 276. Block 276 causes the next block of the test sequence to be performed. A YES result in block 274 indicates that all blocks of the test sequence have been performed, and causes execution to advance to block 278.

In block 278, ATE 212 evaluates the compressed diagnostic information temporarily stored in buffer 244 to determine a test result for memory device under test 210. For example, in an embodiment in which lossless compressor 222 applies run-length coding to the difference patterns, ATE 212 can determine whether the compressed diagnostic information represents one or more difference-indicating patterns, as described above. A difference-indicating pattern is symptomatic of a faulty memory location and, hence, an indication that the memory device under test is faulty. The compressed diagnostic information can be evaluated in other ways to determine a test result for memory device under test 210.

In block 280, the test result is evaluated to categorize memory device under test 210 as good or bad and a category indication is provided. ATE 212 evaluates the test result for memory device under test 210 to categorize the memory device under test and provides the category indication.

In block 282, a test is performed to determine whether the memory device under test 210 is categorized as bad. ATE 212 tests the categorization performed in block 280 to determine whether memory device under test 210 was categorized as bad. A NO result causes execution to return to block 264 via block 286, which causes the next memory device under test to be tested. A YES result causes execution to advance to block 284.

In block 284, where ATE 212 provides diagnostic information for the memory device under test in addition to the category information. Execution then returns to block 264 via block 286.

In one embodiment of block 284, ATE 212 provides the diagnostic information in its compressed state by outputting the compressed diagnostic information temporarily stored in buffer 244. In another embodiment, ATE 212 reads the compressed diagnostic information from buffer 244, expands the compressed diagnostic information to recover the original diagnostic patterns and outputs the recovered diagnostic patterns. In yet another embodiment, ATE 212 reads the compressed diagnostic information from buffer 244 and analyzes the compressed diagnostic information to provide a more concise indication of the fault(s). In an embodiment, the compressed diagnostic information is expanded to recover the original diagnostic patterns before the analysis is performed. In another embodiment, the analysis is performed on the compressed diagnostic information. In an example, the analysis generates a table listing each difference-indicating pattern and the number of the test that yielded such difference-indicating pattern. The table is then output as the diagnostic information for memory device under test 210. The more concise indication can be provided in other ways.

FIG. 6 is a block diagram showing an example of a system 300 in accordance with an embodiment of the invention for obtaining diagnostic information from a memory device comprising memory circuit and a built-in self-test system (BIST). FIG. 6 additionally shows an example of a memory device under test 310 in accordance with an embodiment of the invention. System 300 and memory device 310 each perform a respective embodiment of method 100 described above with reference to FIG. 2 to provide diagnostic information.

System 300 comprises memory device 310 and ATE 312. During each block of the test sequence performed by the BIST, memory device 310 generates diagnostic patterns, losslessly compresses the diagnostic patterns to generate compressed diagnostic information and temporarily stores the compressed diagnostic information. At one or more points in the test sequence, i.e., at the end of each block of the test sequence, memory device 310 outputs the temporarily-stored compressed diagnostic information to ATE 312 and ATE 312 operates deterministically to receive the compressed diagnostic information. In this embodiment, memory device 310 incorporates a buffer that temporarily stores the compressed diagnostic information. The temporarily-stored compressed diagnostic information is output from the buffer at the one or more predetermined points in the test sequence. Elements of system 300 and memory device 310 that correspond to elements of system 200 and memory device 210 described above with reference to FIG. 3 are indicated by the same reference numerals and will not be described in detail again.

Memory device 310 comprises a memory circuit 14, a built-in self-test system (BIST) 216, a difference generator and accumulator (DGA) 220, lossless compressor (LC) 222, a buffer (BUFF) 344 and a diagnostic information output 327. ATE 312 has a test result input 33, a control port 39 and a diagnostic information input 329.

Difference generator and accumulator 320 has an expected pattern input 237, an output pattern input 239, a test result output 31 and a difference pattern output 221. Output pattern input 239 is connected to the read output (RO) of memory circuit 14 to receive the output patterns read from the memory locations of memory circuit 14 defined by the addresses generated by address generator 24 and in response to the control signals generated by control signal generator 28. Expected pattern input 237 is connected to the output of pattern generator 20 to receive the corresponding expected patterns corresponding to the output patterns received at output pattern input 239. As indicated above, the corresponding expected patterns are identical to the test patterns written at the memory locations of memory circuit 14 from which the output patterns are read. A test result path 32 connects test result output 31 to the test result input 33 of ATE 312. Difference pattern output 221 is connected to the diagnostic pattern input 223 of lossless compressor 222. Difference generator and accumulator 320 generates difference patterns from the output patterns read from memory circuit 14 to provide diagnostic patterns corresponding to the output patterns.

Buffer 344 has a compressed diagnostic information input 347, a compressed diagnostic information output 325 and a control input 332. Compressed diagnostic information input 347 is connected to the compressed diagnostic information output 224 of lossless compressor 222. Compressed diagnostic information output 325 provides the diagnostic information output 327 of memory device 310. A diagnostic information path 328 connects diagnostic information output 327 to the diagnostic information input 329 of ATE 329. Control port 332 is connected to the control port 231 of BIST controller 226.

In embodiments of memory device 310 in which lossless compressor 222 applies a lossless compression scheme that generates the compressed diagnostic information in a format that allows a test result for the memory device under test to be easily determined from the compressed diagnostic information, a difference pattern generator similar to difference pattern generator 220 described above with reference to FIG. 3 can be substituted for difference generator and accumulator 320. In such embodiments, test result output 31, test result path 32 and the test result input 33 of ATE 312 are omitted.

Test result path 32 and diagnostic information path 328 are shown in FIG. 6 as multi-conductor parallel paths. A single conductor may provide test result path 32 by interposing a multiplexer (not shown) between the test result output 31 of difference generator and accumulator 320 and test result path 32 and by interposing a demultiplexer (not shown) between test result path 32 and the test result input 33 of ATE 312. Similarly, a single conductor may provide diagnostic information path 328 by interposing a multiplexer (not shown) between diagnostic information output 327 and diagnostic information path 328 and by interposing a demultiplexer (not shown) between diagnostic information path 328 and the diagnostic information input 329 of ATE 312. Alternatively, a single-conductor combined path (not shown) may provide test result path 32 and diagnostic information path 328 by interposing a multiplexer (not shown) the test result output 31 of difference generator and accumulator 320 and diagnostic information output 327 and the single-conductor combined path and by interposing a demultiplexer between the single-conductor combined path and the test result input 33 and the diagnostic information input 329 of ATE 312. Transmitting the test result and the compressed diagnostic information as one or two serial bit streams significantly reduces the number of pins of the package of memory device 310 and the number of communication channels of ATE 312 required to transfer the compressed diagnostic information and the test result from memory device under test 310 to ATE 312.

The above-mentioned multiplexers can be eliminated by serially shifting the test result out of test result output 31 and by serially shifting the compressed diagnostic information out of diagnostic information output 327. The above-mentioned demultiplexers are not needed in embodiments of ATE 312 capable of handling the test result and the diagnostic information as respective serial bit streams.

In an embodiment of memory device 310 in which the output patterns read from memory circuit 14 provide the respective diagnostic patterns corresponding to the output patterns, a conventional difference detector and accumulator similar to difference detector and accumulator 22 described above with reference to FIG. 1A is substituted for difference generator and accumulator 320. Additionally, the read output RO of memory circuit 14 is connected to the diagnostic pattern input 223 of lossless compressor 222 to provide the output patterns read from memory circuit 14 to lossless compressor 222. As noted above, the output patterns may compress less efficiently than difference patterns.

In an embodiment, one or more difference generator and accumulator 320 and lossless compressor 222 comprises additional logic (not shown) controlled by BIST controller 226. Such additional logic prevents difference generator and accumulator 320 from generating a false difference pattern and a false test result from an invalid output pattern and an expected pattern. Such additional logic may additionally prevent lossless compressor 222 from subjecting such false difference pattern received from difference pattern generator 220 to lossless compression. Difference pattern generator 220 may receive an invalid output pattern when BIST 216 reads from a non-existent memory location, for example.

FIG. 7 is a block diagram showing an example of difference generator and accumulator 340 that may be used as difference generator and accumulator 320 in the example of memory device under test 310 described above with reference to FIG. 6. Elements of difference generator and accumulator 340 that correspond to elements of above-described difference generator and accumulator 320 are indicated by the same reference numerals and will not be described in detail again.

Difference generator and accumulator 340 is composed of difference pattern generator 220 and a difference accumulator 322. Difference pattern generator 220 is described above with reference to FIG. 4, and its description will not be repeated here.

Each channel of difference accumulator 322 is composed of an OR gate 73 and a flip-flop 75. In channel CH₁, for example, one input of OR gate 73 is connected to the output of XOR gate 71 in the same channel of difference pattern generator 220. The output of OR gate 73 is connected to the D-input of flip-flop 75. The Q-output of flip-flop 75 is connected to the other input of OR gate 73 and is additionally connected to a respective conductor (not shown) of a cumulative difference bus 357 that extends to test result output 31. Flip-flop 75 additionally has a clock input and a reset line respectively connected to a clock line and a reset line. Neither the clock line nor the reset line is shown to simplify the drawing. Difference generator and accumulator 340 operates similarly to difference detector and accumulator 22 described above with reference to FIG. 1C to generate a cumulative difference D as the test result for memory device under test 310.

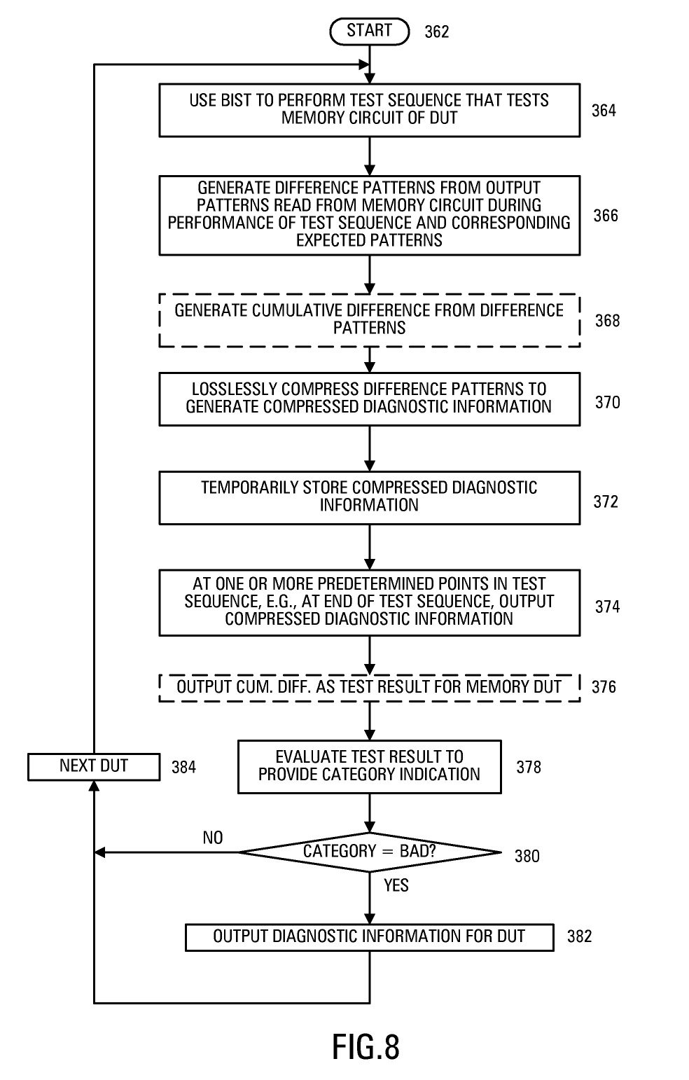

Operation of system 300 to test the memory circuit 14 of memory device under test 310 will now be described with reference to the flow chart shown in FIG. 8 and with additional reference to FIG. 6. In the example shown, the test sequence performed by BIST 216 is not divided into blocks so that the compressed diagnostic information for the entire test sequence is output to ATE 312 at the end of test sequence.

Execution starts at block 362, where ATE 312 initiates testing memory device under test 310 by providing a start testing command to BIST controller 226 via control path 37.

In block 364, BIST 216 performs a test sequence to test the memory circuit 14 of device under test 310. Operation of BIST 216 is similar to that described above with reference to block 264 of FIG. 6, except that, in this example, the test sequence is not divided into blocks.

In block 366, difference patterns are generated from the output patterns read from memory circuit 14 and their corresponding expected patterns. The output patterns are input to the output pattern input 239 of difference generator and accumulator 320 and the corresponding expected patterns are input to the expected pattern input 237 of difference generator and accumulator 320. Difference generator and accumulator 320 generates a difference pattern from each output pattern received at output pattern input 239 and the corresponding expected pattern received at expected pattern input 237 and outputs the difference pattern at difference pattern output 221.

In optional block 368, a cumulative difference is generated from the difference patterns. In the example of difference generator and accumulator 320 described above with reference to FIG. 7, difference accumulator 322 receives each difference pattern generated by difference pattern generator 220 and accumulates the difference patterns to generate the cumulative difference D, as described above. The cumulative difference output at test result output 31 at the end of the test sequence constitutes the test result for memory device under test 310. Block 368 is not performed in embodiments in which ATE 312 determines a test result for memory device under test 310 from the compressed diagnostic information received in block 374, described below.

A block similar to block 368 may be included in embodiments of the method described above with reference to FIG. 5 in which it is difficult or impossible for ATE 212 to determine a test result for memory device under test 210 from the compressed diagnostic information accumulated in block 272.

In block 370, the difference patterns are losslessly compressed to generate compressed diagnostic information. Lossless compressor 222 receives the difference patterns generated by difference generator and accumulator 320 from the output patterns read from the memory locations in memory circuit 14 during execution of the test sequence performed by BIST 216. Lossless compressor 222 losslessly compresses the difference patterns to provide the compressed diagnostic information at compressed diagnostic information output 224.

In block 372, the compressed diagnostic information is temporarily stored. In this embodiment, the compressed diagnostic information is temporarily stored in memory device under test 310, specifically in buffer 344. Buffer 344 receives the compressed diagnostic information generated by lossless compressor 222 at compressed diagnostic information input 347 and temporarily stores the compressed diagnostic information.

In block 374, at one or more predetermined points in the test sequence performed by BIST 216, the compressed diagnostic information is output. In this example, the predetermined point in the test sequence is a single predetermined point the end of the test sequence. At the end of the test sequence, BIST controller 226 provides a control signal at control port 231. Received at the control port 332 of buffer 344, the control signal causes buffer 344 to output the compressed diagnostic information at diagnostic information output 327. Concurrently with the end of the test sequence performed by BIST 216, ATE 312 activates diagnostic information input 329, and ATE 312 receives the compressed diagnostic information. In an embodiment, ATE 312 provides a ready signal at control port 39 when activation of diagnostic information input 329 is complete, and BIST controller 226 waits to receive the ready signal at control port 35 before it provides the control signal to buffer 344. The ready signal indicates that ATE 312 is ready to receive the compressed diagnostic information at diagnostic information input 329.

In optional block 376, the cumulative difference is output as a test result for memory device under test 310. The cumulative difference output at the test result output 31 of difference generator and accumulator 320 constitutes the test result for memory device under test 310. Concurrently with the end of the test sequence performed by BIST 216, ATE 312 activates test result input 33, and ATE 312 receives the test result. In an embodiment, difference generator and accumulator 320 outputs the test result in response to BIST controller 226 receiving a ready signal from ATE 312 in a manner similar to that described above with reference to block 374. Block 372 is not performed in embodiments in which ATE 312 determines a test result for memory device under test 310 from the compressed diagnostic information received in block 374. A block similar to block 376 may be included in embodiments of the method described above with reference to FIG. 5 in which it is difficult or impossible for the ATE to determine a test result for memory device under test 310 from the compressed diagnostic information accumulated in block 272.

In block 378, the test result is evaluated to categorize (good or bad) memory device under test 310 and a category indication is provided. ATE 312 evaluates the test result for memory device under test 310 received at test result input 33 in block 378 to categorize the memory device under test and provides the category indication.

In block 380, a test is performed to determine whether memory device under test 310 is categorized as bad. ATE 312 tests the categorization performed in block 378 to determine whether memory device under test 310 was categorized as bad. A NO result causes execution to return to block 362 via block 384, where the next memory device under test is selected. A YES result causes execution to advance to block 382.

In block 382, the diagnostic information for memory device under test 310 is provided. Exemplary formats in which ATE 312 can provide the diagnostic information are described above with reference to FIG. 5. Execution then returns to block 362 via block 384, described above.

BIST 216 is described above as performing the entire test sequence before the compressed diagnostic information temporarily stored in block 372 is output in block 374, i.e., the one or more predetermined points in the test sequence in which the temporarily-stored compressed diagnostic information is output is a single predetermined point the end of the test sequence. However, in the event that the capacity of buffer 344 proves inadequate to store all the compressed diagnostic information generated during the test sequence, the test sequence can be divided into blocks, and the compressed diagnostic information temporarily stored in buffer 344 can be output at the end of each block of the test sequence. In such an embodiment, the compressed diagnostic information is output at more than one predetermined point in the test sequence, i.e., at the end of each block. ATE 312 temporarily stores the compressed diagnostic information received at the end of each block of the test sequence to accumulate the compressed diagnostic information for the entire test sequence.

Difference patterns are described above as being subject to lossless compression in block 370. Alternatively, the output patterns read in block 364 may be subject to lossless compression to generate the compressed diagnostic information in block 370. In such an alternative, the compressed diagnostic information may be output at a single predetermined point in the test sequence, namely, at the end of the test sequence, or may be output at more than one predetermined point in the test sequence, namely, at the end of each block of the test sequence, as described above. The compressed diagnostic information obtained from the output patterns may be stored in the memory device, in the ATE or in both the memory device and the ATE, as described above.

This disclosure describes the invention in detail using illustrative embodiments. However, the invention defined by the appended claims is not limited to the precise embodiments described.

We claim:

1. A method of deterministically obtaining diagnostic information from a memory device comprising a memory circuit and a built-in self-test system (BIST), the method comprising:
using the BIST to perform a test sequence that tests the memory circuit, the test sequence comprising writing one or more test patterns at memory locations in the memory circuit and reading respective output patterns from the memory locations;
losslessly compressing diagnostic patterns corresponding to the output patterns to generate compressed diagnostic information;
temporarily storing the compressed diagnostic information; and
at one or more predetermined points in the test sequence, outputting the compressed diagnostic information from the memory device under test.

2. The method of claim 1, in which the diagnostic patterns corresponding to the output patterns comprise the respective output patterns.

3. The method of claim 1, in which:
the method additionally comprises generating a respective difference pattern between the output pattern read from each one of the memory locations and a corresponding expected pattern identical to the one of the test patterns written at the one of the memory locations; and
the diagnostic patterns corresponding to the output patterns comprise the respective difference patterns.

4. The method of claim 1, in which the storing comprises storing the compressed diagnostic information in the memory device.

5. The method of claim 1, in which the one or more predetermined points in the test sequence is a single point the end of the test sequence.

6. The method of claim 1, in which:
the test sequence comprises blocks;
the compressing comprises losslessly compressing the difference patterns corresponding to the output patterns read during execution of each block of the test sequence to generate respective compressed diagnostic information, and the outputting comprises outputting the respective compressed diagnostic information at the end of each block of the test sequence.

7. The method of claim 6, in which the storing comprises storing the compressed diagnostic information output at the end of each block of the test sequence to accumulate the compressed diagnostic information for memory device under test.

8. The method of claim 6, additionally comprising changing the size of the blocks in response to a change in production yield.

9. The method of claim 6, additionally comprising:
determining whether the compressed diagnostic information output at the end of the block of the test sequence represents no fault-indicating diagnostic patterns; and
when the compressed diagnostic information represents no fault-indicating diagnostic patterns, discarding the compressed diagnostic information.

10. The method of claim 1, additionally comprising, after the outputting, expanding the compressed diagnostic information to recover the diagnostic patterns.

11. The method of claim 1, additionally comprising determining a test result for the memory device from the diagnostic information.

12. The method of claim 1, additionally comprising:
generating a test result for the memory device under test; and
outputting the test result from the memory device under test.

13. The method of claim 1, in which:
the method additionally comprises connecting the memory device to automatic test equipment; and
the outputting comprises outputting the compressed diagnostic information from the memory device under test to the automatic test equipment.

14. The method of claim 1, in which:
the method additionally comprises connecting the memory device to automatic test equipment; and
the storing comprises storing the compressed diagnostic information at the automatic test equipment.

15. A device, comprising:
a memory circuit;
a built-in self-test system (BIST) operable to perform a test sequence that tests the memory circuit, the test sequence comprising a write operation in which one or more test patterns are written at memory locations in the memory circuit, and a read operation in which respective output patterns are read from the memory locations;
a lossless compressor connected to receive from the BIST diagnostic patterns corresponding to the output patterns, the compressor operable to compress the diagnostic patterns losslessly to generate compressed diagnostic information; and
a diagnostic information output coupled to receive the compressed diagnostic information generated by the lossless compressor and operable at one or more predetermined points in the test sequence to output the compressed diagnostic information.

16. The device of claim 15, additionally comprising a buffer connected to receive the compressed diagnostic information and operable to store the compressed diagnostic information temporarily, the buffer additionally operable at the one or more predetermined points in the test sequence to output the compressed diagnostic information to the diagnostic information output.

17. The device of claim 15, in which the diagnostic patterns corresponding to the output patterns comprise the respective output patterns.

18. The device of claim 15, additionally comprising a difference pattern generator connected to the BIST to receive the output patterns and, for each of the output patterns, a corresponding expected pattern identical to the test pattern written at the memory location from which the one of the output pattern was read, the difference pattern generator operable to generate respective difference patterns from the output patterns and the corresponding expected patterns as the diagnostic patterns corresponding to the output patterns.

19. The device of claim 18, additionally comprising a difference accumulator connected to receive the difference patterns from the difference pattern generator and operable to generate a cumulative difference from the difference patterns.

20. A system, comprising:
deterministically-operating automatic test equipment; and
a memory device connected to the automatic test equipment, the memory device comprising:
a memory circuit,
a built-in self-test system (BIST) operable to perform a test sequence that tests the memory circuit, the test sequence comprising a write operation in which one or more test patterns are written at memory locations in the memory circuit, and a read operation in which respective output patterns are read from the memory locations;
a lossless compressor connected to receive from the BIST diagnostic patterns corresponding to the output patterns, the compressor operable to compress the diagnostic patterns losslessly to generate compressed diagnostic information; and
a diagnostic information output coupled to receive the compressed diagnostic information generated by the lossless compressor and operable at one or more predetermined points in the test sequence to output the compressed diagnostic information to the automatic test equipment.

21. The system of claim 20, additionally comprising a buffer connected to receive the compressed diagnostic information and operable to store the compressed diagnostic information temporarily.

22. The system of claim 21, in which the buffer constitutes part of the memory device, is connected to receive the compressed diagnostic information from the lossless compressor and is operable at the one or more predetermined points in the test sequence to output the compressed diagnostic information to the ATE.

23. The system of claim 22, in which the one or more predetermined points in the test sequence is a single point at the end of the test sequence.

24. The system of claim 21, in which the buffer constitutes part of the ATE and is connected to receive the compressed diagnostic information from the memory device at the one or more predetermined points in the test sequence.

25. The system of claim 20, in which the diagnostic patterns corresponding to the output patterns comprise the respective output patterns.

26. The system of claim 20, the memory device additionally comprises a difference pattern generator connected to the BIST to receive the output patterns and, for each of the output patterns, a corresponding expected pattern identical to the test pattern written at the memory location from which the one of the output pattern was read, the difference pattern generator operable to generate respective difference patterns from the output patterns and the corresponding expected patterns as the diagnostic patterns corresponding to the output patterns.
